(19) United States
(12) Patent Application Publication
(10) Pub. No.: US 2007/0157873 A1
(43) Pub. Date: Jul. 12, 2007

(54) Method of fabrication and device comprising elongated nanosize elements

(76) Inventors: Jonas Rahlf Hauptmann, Copenhagen N (DK); Ane Jensen, Copenhagen V (DK); Poul Erik Gregers Hansen Lindelof, Broenshoej (DK); Jesper Nygaard, Frekderiksberg (DK); Janusz Sadowski, Warszawa (PL)

Correspondence Address: KNOBBE MARTENS OLSON & BEAR LLP, 2040 MAIN STREET, FOURTEENTH FLOOR, IRVINE, CA, 92614, US

(21) Appl. No.: 10/571,520

(22) PCT Filed: Sep. 10, 2004
(86) PCT No.: PCT/DK04/00603

§ 371 Date: Dec. 22, 2006

(30) Foreign Application Priority Data
Sep. 12, 2003 (DK) PA 2003 01325

(51) Int. Cl. C30B 13/00; C30B 23/00; C30B 25/00; C30B 28/12

(52) U.S. Cl. 117/87; 117/84; 117/45

(57) ABSTRACT

A method of fabricating devices comprising elongated nanosize elements as well as such devices are disclosed. The devices comprise epitaxially grown layers into which elongated nanosize elements, such as carbon nanotubes, are incorporated. A substrate supporting epitaxial growth of an epitaxial layer is provided, elongated nanosize elements is provided onto the substrate and epitaxially overgrown with an epitaxial layer. The elongate nanosize elements are thereby at least partly encapsulated by the epitaxially grown layer. One or more components are prepared in the layer, the one or more components being prepared by means of lithography. Devices with carbon nanotubes as the active element may thereby be provided. The method is suitable for hybrid devices, hybrid between conventional semiconductor devices and nano-devices.

### FIELD OF THE INVENTION

The invention relates to devices comprising elongated nanosize elements and the fabrication of the devices. The devices comprise epitaxially grown layers into which elongated nanosize elements, such as carbon nanotubes, are incorporated.

### BACKGROUND OF THE INVENTION

Ever since the appearance of the integrated circuit and the computer chip, the performance of such devices has been increasing at a remarkable pace, an advancement primarily driven by progress in the ability to miniaturise basic components of integrated circuits and increase the density of components in a chip resulting in integrated electronic devices performing more functions per unit area. The technology is, however, getting close to reach the limit of what is possible with respect to miniaturisation of conventional components, such as e.g. the metal-on-oxide field effect transistor (MOSFET). For example, geometrical structures are getting near the limit with respect to heat dissipation and stability of the structures due to diffusion of matter, and at the same time the lithographic techniques used to define the structures of the circuits are getting near their resolution limit.

Different types of elongated nanosize elements exist, one important example is the carbon nanotubes. Carbon nanotubes are nanostructured tubular molecules of carbon. The nanotubes possess electric as well as mechanical properties potentially very useful for a number of technological applications. The nanotubes exists both as multi-wall carbon nanotubes and as single-wall carbon nanotubes.

The small dimensions of elongated nanosize elements, such as carbon nanotubes, make the handling of the elongated nanosize elements quite challenging. Some ways of incorporating carbon nanotubes into devices have been suggested. U.S. Pat. No. 6,515,325 and U.S. Pat. No. 5,581,091 both disclose the growth of material on vertical nanotubes, where only the end or terminal surface of a nanotube is overgrown. WO 00/63115 and WO 02/081366 both disclose the possibility of forming a nanotube containing layer by pyrolysis on a glass substrate and afterwards overgrow the nanotube containing layer by another material to form components, such as field effect transistors (FETs), electrodes, etc.

In many applications, the use of an epitaxially grown material is a prerequisite for forming certain structures and the epitaxially grown materials form the backbone in many technological applications, such as chip production and the production of e.g. optical, electronic, mechanical and sensor components.

### SUMMARY OF THE INVENTION

It is an object of the present invention to provide a method of overgrowing elongated nanosize elements with an epitaxial material.

It is a further object of the present invention to provide a method for manufacturing a device which is superior to conventional electronic devices of the integrated circuit type.

According to a first aspect of the invention, the above-mentioned and other objects are fulfilled by providing a method of overgrowing elongated nanosize elements with at least one epitaxial layer, the method comprising the steps of:
(a) providing a substrate, wherein the substrate or at least a top layer of the substrate has a surface supporting epitaxial growth of an epitaxial layer,
(b) providing elongated nanosize elements onto the substrate,
(c) epitaxially overgrowing the substrate and the elongated nanosize elements with an epitaxial layer and thereby at least partly encapsulating the elongated nanosize elements into the epitaxially grown layer, and
(d) preparing one or more components in the layer, the one or more components being prepared by means of lithography.

The elongated nanosize elements may be any type of elongated nanosize elements, such as nanotubes, nanowires, such as nanorods or nanowhiskers. The elongated nanosize elements may also be elongated macro-molecules, such as a protein, and the elongated nanosize element may be elongated nanosize polymer molecules, such as DNA. The elongated nanosize elements may be inorganic or organic nanosize elements, the elongated nanosize element may also be a chain of molecules, such as a polymer chain, or the elongated nanosize elements may be a single elongated molecule such as carbon-70. The elongated nanosize elements may possess any type of elongated shape, such as substantially cylindrical shaped, substantially ellipsoidal shaped, etc.

The nanosize elements may be seamless elements, such as a seamless solid element or a seamless hollow element, possibly provided with a core structure. The nanosize element may be provided to the substrate from an external source, i.e. not grown or synthesised directly on the substrate. The nanosize element may be the active structure of the one or more components, such as a single element constitutes the active structure, a bundle of elements constitutes the active structure or a plurality of elements constitutes the active structure.

The nanosize elements may be synthesised chemically, grown epitaxially, grown by catalytic decomposition of e.g. hydrocarbon gases, or provided by any other means as known in the art.

The nanosize elements may be insulating, semiconducting or metallic, depending upon the properties of the nanosize element material and of possible additives to the material, such as dopants. The nanosize elements may have a length of up to 1 centimeter, such as up to 0.5 cm, such as up to 5 μm, such as up to 1000 nm, such as up to 500 nm, such as up to 250 nm, such as up to 100 nm. The nanosize elements may have a length from 1 nm to 1 cm, such as from 100 nm-1000 μm, such as from 250-500 nm. The diameter of the elements may vary from below 1 nm to the order of 10's of nanometer, such as from 0.1-100 nm, such as from 1-50 nm, such as from 2-40 nm, such as from 3-30 nm, such as from 4-20 nm, such as from 5-10 nm.

A preferred nanosize element may be a carbon nanotube. The carbon nanotubes may be single-walled or multi-walled as also mentioned above. The typical diameter of a single-wall nanotube is of the order of 1 nm, whereas the multi-wall nanotube may obtain diameters in the order of 10's of nm. The carbon nanotubes may have lengths up to about 1 centimeter, but the lengths are normally in the micrometer range. The carbon nanotubes may be semiconducting, either intrinsic semiconducting or doped semiconducting and in some applications it is preferred to use strongly doped semiconducting nanotubes. The nanotubes may further be conducting, such as metallic conductors. Both types are characterised by one-dimensional (1D) transport of electrons in the tube direction.

The one or more components may be prepared by using lithographically defined structures followed by etching. The one ore more components may e.g. be prepared by using one of the following standard lithography techniques, singly or in combination: e-beam, X-ray beam, ion-beam, UV-lithography, AFM-lithography, nano-imprint lithography, shadow mask technique, etc.

Overgrowing elongated nanosize elements with an epitaxial layer provides for an epitaxial layer with elongated nanosize elements incorporated therein. Depending upon exactly how the elongated nanosize elements are incorporated in the epitaxial layer, the epitaxial layer may be used as an important element in a number of technical applications.

According to further aspects of the invention, the above-mentioned and other objects are fulfilled by providing a method of fabricating an electronic device and/or a component as well as by providing an electronic device and/or component.

The device may be an electronic device such as an integrated circuit device comprising at least one integrated electronic component of the metal-on-oxide type. Thus, the device may be an integrated circuit device corresponding to conventional semiconductor integrated circuits, however with improved characteristics resulting from the incorporation of elongated nanosize elements into the epitaxial layer. Furthermore, the device may be any other type of device according to the present invention, such as light emitting devices, electron emitting devices, spin-tronics devices, sensor devices, etc.

The components may be prepared comprising any type of elongated nanosized elements, such as for example comprising either single-walled or multi-walled nanotubes, and the components may be prepared comprising a mixture of single-walled and multi-walled nanotubes.

Due to the small size of elongated nanosize elements, such as carbon nanotubes, compared to conventional transistor components, integrated circuits occupying less space may be provided. Additionally due to the excellent thermal conductivity of elongated nanosize elements such as carbon nanotubes, problems with heating are suppressed when using carbon nanotubes, or other types of elongated nanosize elements with excellent thermal conductivity, in integrated circuits compared to integrated circuits using conventional transistor components further facilitating the stacking of more components on less space.

As the size of integrated circuits decreases, the computation speed of the circuits increases, since signals travel shorter distances. By using an elongated nanosize element such as a carbon nanotube as e.g. the channel in a CMOS based transistor or as the base in a bipolar transistor, the power consumption of the devices may be significantly reduced due to the low losses obtained by the use of carbon nanotubes. Preferably, the device may be a device comprising epitaxially grown semiconducting hetero-structure components.

The elongated nanosize element overgrown by an epitaxial layer and thus forming a layer containing elongated nanosize elements may be used as a heat dissipating layer due to the high thermal conductivity of many types of elongated nanosize elements, such as carbon nanotubes, platinum nanowires, etc. The substrate and the overgrown elongated nanosize elements may thus form the basis for fabricating devices comprising for example high power components, lasers, or other heat generating components, wherein the overgrown elongated nanosize elements may provide a layer which remove, conduct, dissipate, or transport heat in any way through or away the from the layer.

The thermal conductivity of for example a carbon nanotube is dependent on several factors, such as the cell length along the nanotube, the type of nanotube and the temperature. The thermal conductivity may be between 1500-6000 W/mK, such as between 2000-3500 W/mK, such as between 2600 and 3200 W/mK, such as 3000 W/mK measured at 300 K.

Heat dissipated in the structure by components or devices fabricated in and on top of epitaxial materials grown on top of the heat dissipating elongated nanosize element containing layers may then be conducted away from the components or devices, to ensure cooling of the devices and avoid overheating. Thus, the elongated nanosize element containing layers may therefore provide a heat transporting layer for a component in e.g. an electronic chip for transporting heat in connection with high current densities passing through critical areas, since in many electronic components overheating during operation is a crucial aspect of the performance of the component.

Elongated nanosize elements incorporated in epitaxial materials may also be used as a mechanical device, e.g. in nano-electro mechanical systems (NEMS). For example, a carbon nanotube freely hanging between two epitaxial material patches may be oscillating at very high frequencies, such as at GHz. Nanotubes oscillating at GHz may provide devices which can oscillate at frequencies comparable to electromagnetic frequencies used in telecommunication, and thereby for example function as the sensing element in a NEMS sensor capable of detecting electromagnetic radiation at frequencies used in telecommunication.

A substrate supporting epitaxial growth is first provided. The role of the substrate is at least twofold, the substrate is a carrier of the device at least throughout the fabrication of the device, and the substrate determines the nature of the epitaxially layer which may be grown on the substrate. The choice of substrate is therefore based on the nature of the desired epitaxial layer. The substrate may be a layered substrate comprising a few or many layers or the substrate may be formed of a single material in a single layer. In the case the substrate is layered, only the top layer of the substrate may support epitaxial growth. In order for the substrate to support epitaxial growth, the surface of the substrate is preferably substantially well-ordered, i.e. the surface of the substrate is preferably substantially crystalline, preferably a substantially mono-crystalline material.

Depending upon the nature of the substrate and the epitaxial layer, an epitaxial layer may be grown which is either matched, or strained. That is, if there is a lattice mis-match between the substrate or at least the top layer of the substrate and at least the bottom layer of the epitaxial layer, the epitaxial layer may be strained, whereas if there is substantially no mis-match between the substrate and the epitaxial layer, substantially no strain may build up in the epitaxial layer.

Elongated nanosize elements are provided onto the substrate and the substrate including the elongated nanosize elements are overgrown with an epitaxial layer, so that the material of the epitaxial layer is in an epitaxial coordination with the crystal underneath the elongated nanosize elements. Having, e.g., carbon nanotubes encapsulated in the epitaxial layer enables a unique combination of the physical properties, such as the inherently small size, the heat conductivity and the strength of the carbon nanotubes with the well-known properties of epitaxially grown structures, such as the ability of forming a variety of well-characterised semiconductor components therein, while maintaining the versatility of epitaxially grown structures, allowing e.g. to prepare one or more carbon nanotube containing components in the epitaxial layer using a lithographic technique. Many different configurations of elongated nanosize elements may be envisioned. The elongated nanosize elements may, e.g. serve as an interconnection between components comprised in the integrated circuit. Or, different layer sequences may be provided, such as a three layer sequence (a, b, c) continued as a multi-layer system, e.g. (a, b, c, b, d, e, . . . ), where b is the carbon nanotube, whereas a, c, d, e, . . . may represent electrodes or semiconducting device layers, etc.

The use of epitaxially grown materials offers an important means of controlling the atomic/molecular composition of devices with a very high precision, and as importantly also the doping profiles may be controlled very accurately. For example, a semiconductor layer with a relatively low doping concentration may be grown epitaxially upon a substrate which contains the same type of dopant in a much higher concentration. This may for example be used for the fabrication of transistors having a very thin base region and thus being effective for high frequency operation. Generally, an important advantage of epitaxially grown materials is the abrupt change of properties without disrupting the growth of the single crystal. Important usage of this are quantum wells for field effect transistors and lasers. A band off-set may also be incorporated in bi-polar transistors.

Fabrication of, e.g., electronic devices is highly optimised, rendering the inclusion of new aspects into the fabrication process difficult. The present invention is compatible with existing technology, since for certain aspects of the invention, only a few additional process steps are necessary in order to include elongated nanosize elements into the device. Furthermore, substrates comprising the elongated nanosized elements overgrown by an epitaxial layer may be provided from a substrate provider, thus necessitating substantially no modification in the manufacturing process. The invention thus cover the entire range from slight modification of the fabrication method in order to obtain structurally similar devices with improved characteristic, over hybrid devices where certain aspects of the device comprise conventional components, whereas certain areas of the device comprise elongated nanosize element improved components, to devices substantially comprising elongated nanosize element improved components.

The epitaxial layer may be a semiconducting layer, thereby enabling components formed at least partly within the epitaxial semiconducting layer to be semiconductor components, and thereby forming a semiconductor device. The semiconducting layer may be an intrinsically, i.e. an undoped, semiconductor layer, or an extrinsically, i.e. a doped, semiconductor layer. A component which includes the epitaxial layer may or may not include an epitaxial layer comprising elongated nanosize elements. An integrated circuit based on components which include the epitaxial layer may comprise both components comprising elongated nanosize elements and components which do not comprise elongated nanosize elements. The components formed in the semiconducting layer may be interconnected using elongated nanosize elements, or with interconnections comprising elongated nanosize elements. The epitaxial layer may also be a strongly doped semiconductor layer or a metallic layer, in which cases the layer for example may can be used as a back gate in a field effect transistor.

The epitaxial layer may be grown using one or more of several different techniques, e.g. by molecular beam epitaxy (MBE) which is a preferred growth method for many combinations of materials, e.g. GaMnAs, GaAs and has the advantage of enabling precise and very well-defined interfaces between different materials. However, other material combinations may be grown by chemical vapor deposition processes, such as chemical vapor deposition (CVD), metal-organic CVD (MOCVD), metal-organic vapor phase epitaxy (MOVPE), ultra-high vacuum CVD (UHVCVD), Chemical beam epitaxy (CBE), or by a liquid phase deposition (LPE) process. These techniques all allow high growth rates which are useful for production of thicker epitaxial layers.

The thickness of the epitaxial layer may vary according to the specific component and according to the epitaxial material and the growth technique applied. An epitaxial layer may be grown which is only one atom layer thick, i.e. with a thickness around 0.1 nm, and with a thickness up to one millimeter. Accordingly, the thickness of the epitaxial layer may be between 5 nm and 5 μm, such as between 5 nm and 1 μm thick, such as between 5 nm and 500 nm thick, such as between 5 nm and 100 nm thick, such as between 10 and 75 nm thick, such as between 20 and 50 nm thick, such as between 20 and 30 nm thick.

The epitaxial layer may be magnetic. The epitaxial layer may be magnetic in addition to be semiconducting, however, the epitaxial layer may also be magnetic irrespectively of the conductivity of the epitaxial layer. A magnetic layer enables electronic components utilising the spin of the electrons, and thereby enables so-called spin-tronic components. Spin-tronic utilises the spin state of the electrons, resulting in new devices with new functionality. Furthermore, spin-tronic devices typically will have low power consumption and high switching speed compared to electronic devices. Spin-tronic devices are faster than devices using electrical charges, since no charge RC time constant is present in spin-tronic devices.

The epitaxial layer may be comprised of such materials as GaMnAs, GaAlAs, GaAs, SiGe, GaInAs, InP, Si, SiGe, GaN, GaAlN, Al, Ag, Au, Cu, metallic alloys like MnGa and single and double Heusler alloys (CoMnGa, Co2MnGa) and half-metallic ferromagnetics, organic semiconductors, such as for instance 3,4,9,10-perylenetetracarboxylic, 3,4,9,10-dianhydride (PTCDA) and 4,9,10-perylene-tetracarboxylic-dianhydride (PTCDA) dye molecules.

It is an advantage of epitaxial materials that post processing, such as lithographically definition of structures, may be made more precisely and reproducibly in an epitaxial material than in non-epitaxial materials, such as amorphous materials. Furthermore, the use of epitaxial layer structures may allow growing e.g. etch stop layers in order to provide an optimal control of the structure in cases where etching is used.

The substrate, or at least the top layer of the substrate may be a semiconductor. The substrate or at least the top layer of the substrate may be semiconducting so that the material of the substrate or at least the top layer of the substrate is an intrinsic semiconductor material. The substrate or at least the top layer of the substrate may also be a doped semiconductor, and the substrate or at least the top layer of the substrate may be doped to be n-type or p-type.

The substrate may comprise such materials as: GaAs, Si, SiN, SiC, glass, metal oxides, such as Al₂O₃. The substrate may also include quantum wells, 2-dimensional electron gases, laser structures, optical detectors, etc. Furthermore, the substrate may be any substrate providing a basis for epitaxial overgrowth of any materials, such as any of the materials as mentioned above.

The substrate, or at least the top layer of the top layer of the substrate may be grown by molecular beam epitaxy, by a chemical vapor deposition process (MOCVD or UHVCVD) or by a liquid phase deposition process, or by any other growth method. The substrate may be any commercially available crystalline substrate, such as any Czochralski, Bridgmann or float zone grown material or any material grown by physical vapor transport or any flux grown material.

In order to facilitate proper alignment of e.g. lithography masks, or in order to render location of specific areas on the surface of the device more easy, or for any other reason, the substrate and/or the top layer may comprise alignment marks. The alignment marks may have the form of protrusions, such as bumps, or depressions and the alignment marks may have any shape. The alignment marks may be formed during any stage of the process, and the alignment marks may later on in the process be covered by e.g. the material used to form the epitaxial layer. Normally, the alignment marks may have a size and structure so that the possible covering of the marks by additional material does not affect the purpose of the marks, e.g. location or relocation of specific areas. The alignment marks may e.g. be made by focused ion-beam lithography, optical or e-beam lithography (followed by evaporation or etching), stamping, mechanical indentation, etc.

The substrate or at least the top layer of the substrate may be covered with a barrier, i.e. a barrier may be provided between the substrate and the epitaxial layer. The barrier may for example be a buffer layer provided in order to match the lattice constants of at least the top layer of the substrate and the epitaxial layer. The lattice constants may be matched by providing a substantially perfect interface between at least the top layer and the epitaxial layer. A barrier may also be provided to hinder inter-diffusion between the substrate and the epitaxial layer, or for any other reason.

The barrier may also be an insulating layer provided in order to insulate the substrate from the epitaxial layer, e.g. to insulate the back-gate from the device in a transistor type device. In this case the barrier is an abrupt change between two materials in order to impose an abrupt change in the electric properties around the bordering zone between the materials on both sides of the barrier. The barrier may either impose an electric barrier due to different electrical properties between either the substrate and the barrier or between the barrier and the epitaxial layer. The barrier may also act as a tunnel barrier between the substrate and the epitaxial layer, as e.g. in the case of a GaAs/AlAs super lattice between two GaAs layers.

The barrier may comprise a stack of layers, for example so that the barrier may be build up of a series of alternating layers. At least one of the layers may comprise a material corresponding to the material of the substrate or the material of the top layer. That is, if the substrate is a GaAs-substrate, the barrier may comprise e.g. Ga, for example in the form of a GaAs layer. Or, the barrier may comprise e.g. As, for example in the form of an AlAs layer. Alternatively, the barrier may comprise layers of materials wherein the composition of the materials in the layers are gradually changed. For example, a barrier layer on a Si surface may comprise a silicon layer, wherein the amount of e.g. Ge is gradually increased to match that of an epitaxial layer of SiGe, so that an epitaxial layer of SiGe may be grown on the barrier, wherein the stress is reduced due to the presence of the barrier, so that for example the density of dislocations are reduced compared to the growth of a strained SiGe layer without the barrier.

The barrier may form a super-lattice. That is, the barrier may be a periodic structure consisting of alternating ultrathin layers with its period less than the electron mean free path of electrons in the alternating layer.

The layers in the stack of layers may be between 1 and 5 nm thick, such as between 1 and 3 nm thick, such as between 2 and 4 nm thick, such as 2 nm thick. Resulting in a thickness of the stack of layers between 5 nm and 1000 nm, such as between 25 nm and 750 nm thick, such as between 50 nm and 500 nm thick, such as between 75 nm and 250 nm thick, such as 100 nm thick. The thickness of the stack depends both on the thickness of the layers, as well as the number of layers. For example, 100 layers of a first kind, e.g. GaAs, may be alternating with 100 layers of a second kind, e.g. AlAs, resulting in a barrier comprising 200 layers.

The substrate or at least the top layer of the substrate may be covered by a first protection layer. In the case where the substrate is covered by a barrier, the barrier rather than the substrate, may be covered by the first protection layer.

In order to be able to grow an epitaxial layer on top of a material, the surface quality of the material is essential for the growth. For example, oxidation due to exposure to ambient air, adhesion of other components such as ambient carbon from the air, dust particles, etc. may be so damaging that an epitaxial layer cannot be grown. It is therefore of importance to ensure that the surface of either the substrate, the top layer of the substrate or the barrier is of a kind so as to allow for epitaxial growth, i.e. so that the surface is molecular smooth and free of unwanted species such as oxygen.

The first protection layer may be provided in order to protect the surface region of the material below the protection layer. It may e.g. be necessary to expose the surface to ambient air after the barrier has been prepared in a first growth chamber, such as a first MBE chamber, whereas additional process steps may occur in a second growth chamber, such as a second MBE chamber, or a CVD chamber.

Furthermore, it may be necessary to expose the surface to ambient air during deposition of the elongated nanosize elements, or at least to expose the surface to ambient air during transportation of the substrate from a growth chamber to a elongated nanosize element deposition chamber and back to a growth chamber.

The surface region of the barrier may be destroyed if exposed to ambient air, and therefore a first protection layer may be provided.

The first protection layer may be provided in order to protect the barrier or the substrate before further processing occurs, e.g. due to that it is necessary to expose the intermediate device, for example the substrate with or without the elongated nanosize elements, to harmful conditions. However, the intermediate device may be reinstated in an environment which is not malign to the device, and before the process of preparation may continue, it may typically be necessary to remove the first protection layer.

The first protection layer may be a layer of amorphous arsenic, sulphur, hydrogen, oxygen, or any other layer of material which may be removed e.g. in the growth chamber, without damaging the elongated nanosize elements, the substrate, any barrier present or any components already present in the substrate.

The process of fabricating the device may thus for example comprise the step of annealing prior to the step of epitaxially overgrowing the substrate and the elongated nanosize elements. This step may be provided in order to remove the first protection layer without affecting neither the substrate or at least the top layer of the substrate, nor any barrier present, nor the deposited elongated nanosize elements. Preferably, the first protection layer is evaporated at a temperature which is lower than any temperature which degrades the remaining of the device and the elongated nanosize elements. In the case where the first protection layer is amorphous arsenic and the elongated nanosize elements are carbon nanotubes, the carbon nanotubes possess a relatively large contact surface to the arsenic layer and the arsenic layer sublimate atom by atom, whereby the carbon nanotubes remain on the surface in the same configuration as they were deposited, both during and after the evaporation of the arsenic layer.

The epitaxial layer may be covered by a second protecting layer, the second protecting layer may be between 2 nm and 500 μm thick, such as between 10 nm and 250 μm, such as between 25 nm and 100 μm, such as between 50-1000 nm, such as between 100-500 nm, such as 250 nm thick. The second protection layer may be provided on top of the epitaxial layer overgrowing the elongated nanosize elements in order to permanently protect device(s) from the influence of the ambient air, e.g. to protect the device(s) mechanically against scratches, dust particles, etc.

The components may be prepared using either semiconducting or conducting elongated nanosized elements, such as nanotubes, and the components may be prepared using a mixture of semiconducting and conducting elongated nanosized elements. For example, interconnections may be or may comprise elongated conducting nanosized elements, whereas elongated nanosized elements incorporated into the individual components may be semiconducting.

The elongated nanosized elements may be provided in any material capable of forming an elongated nanosized element, i.e., it may be made of Carbon, Si, SiC, B, BN, Pt, SiGe, Ge, Ag, Pb, ZnO, GaAs, GaP, InAs, InP, Ni, Co, Fe, Pb, CdS, CdSe, SnO₂, Se, Te, Si₃N₄, MgB₂, etc.

The elongated nanosized elements may be provided to the surface by any known technique. The technical field of nanosized elements, such as carbon nanotubes is developing at a remarkable pace and it is envisaged that any method may be used to provide the elongated nanosized elements to the surface. The elongated nanosized elements may be produced using a number of methods and subsequently provided to the surface supporting epitaxial growth. For example, carbon nanotubes may be produced using laser ablation, the arc method, chemical vapor deposition (CVD) or high-pressure CO conversion (HIPCO) synthesis. Also, the carbon nanotubes may be provided onto the substrate by means of liquid deposition. Further, islands or particles of catalytic material may be provided to the substrate and the carbon nanotubes may be grown on the substrate from the catalytic material. It is presently preferred to provide laser ablated carbon nanotubes to the surface using liquid deposition.

The specific choice of growth method depends among other aspects, upon the growth temperature and the growth temperature of the epitaxial layer. For example, carbon nanotubes grown using the CVD technique may be used when the epitaxial layer is for example Si, SiGe or GaN since both the growth temperature of the CVD carbon nanotubes and the growth temperatures of these epitaxial layers are around 900-1000° C.

It may be necessary to manipulate the placement of the nanotubes, or any other type of elongated nanosize elements, prior to depositing the epitaxial layer in order to obtain a specific orientation or positioning of the elongated nanosize elements on the substrate. The elongated nanosize elements may be manipulated using an atomic force microscope (AFM). The AFM may be scanned across the surface in a predefined way one or many times resulting in a well defined spatial distribution of the nanotubes on the surface. The spatial distribution of the elongated nanosize elements may also be controlled by applying electro-magnetic fields. The spatial distribution of the elongated nanosize elements may e.g. also be controlled by preparing the surface onto which the elongated nanosize elements are provided, i.e. the surface of the substrate or the surface of the barrier, in such a way that the elongated nanosize elements adopt a well defined spatial distribution. Also, the elongated nanosize elements may be grown in a liquid or gas flow and align according to the flow. Furthermore, the elongated nanosize elements may be chemically modified in such a way that interactions between the elongated nanosize elements result in a well-defined spatial distribution.

It is, however, not for all aspects of the present invention that the spatial distribution of the elongated nanosize elements needs to be manipulated. The elongated nanosize elements may be provided to the surface in a way so that the elongated nanosize elements reside in a random or apparently or substantially random way. It may be advantageous for certain hetero-structures that elongated nanosize elements are incorporated into the epitaxial layer. For example in the case where the elongated nanosize elements are carbon nanotubes, the carbon nanotubes ability to withstand high current densities may provide components with an improved performance, or the carbon nanotubes ability to remove heat may provide components which does not require extensive cooling in order to operate.

Metallic contact pads may for example be prepared and connected to the components by means of lithography and lift-off. Metallic contact pads may be prepared e.g. in order to contact the component to a standard chip carrier.

The component may be an electronic component, such as one of the following electronic transistors: JFET, MESFET, MOSFET, bipolar transistor, Schottky diode transistor, spinvalve transistor, single electron transistor, etc.

A elongated nanosize element such as a carbon nanotube may e.g. act as the gate element of the transistor.

The electronic component may also be one of the following electronic components: p-n diode, Schottky diode, rectifier, cryotron device, high frequency Josephson junction oscillator and non-linear detector, superconducting quantum interference device (SQUID), etc.

In this case the carbon nanotube or another type of elongated nanosize element may e.g. act as a connecting element in the electronic component.

The electronic component may also be a charge or spin memory component, where the nanotube or other type of elongated nanosize element act as the charge or spin storing part.

The device may be an electronic device. For example, the device may be an integrated circuit.

The electronic device may be an electronic circuit comprising one or more of the aforesaid electronic components.

The elongated nanosize element may act as an interconnection between any of the electronic components in the electronic device. The elongated nanosize elements may e.g. act as an interconnection between all the electronic components or between some of the electronic components. Alternatively, the elongated nanosize elements may be incorporated in the interconnection between the electronic components.

A monolithic integrated circuit system may be formed by repeating the above-mentioned method. That is, a monolithic integrated circuit may be formed by forming one layer at the time according to the above-mentioned method until a monolithic integrated circuit is completed.

The elongated nanosize elements containing epitaxial layer may act as a heat conducting layer. For example, one or more layers of layers may be provided in a monolithic integrated circuit in order to provide a monolithic integrated circuit with improved heat conducting abilities.

An optical device, a NEMS or a sensor device may also be provided by the above- mentioned method.

It will be appreciated that features of the invention are susceptible to being combined in any combination without departing from the scope of the invention.

The features and/or advantages of the invention will be apparent from and elucidated with reference to the embodiments described hereinafter.

### BRIEF DESCRIPTION OF THE DRAWINGS

Preferred embodiments of the invention will now be described in details with reference to the drawings in which:

FIG. 1 illustrates a nanotube FET,

FIGS. 2a-2d illustrate the fabrication of a device according to the invention,

FIGS. 3a-3c illustrate a device which is bonded on a chip carrier,

FIG. 4 illustrates a 2D electron gas FET,

FIG. 5 illustrates a laser incorporating a nanotube, and

FIG. 6 illustrates a nano-electro mechanical system.

### DETAILED OF PREFERRED EMBODIMENTS

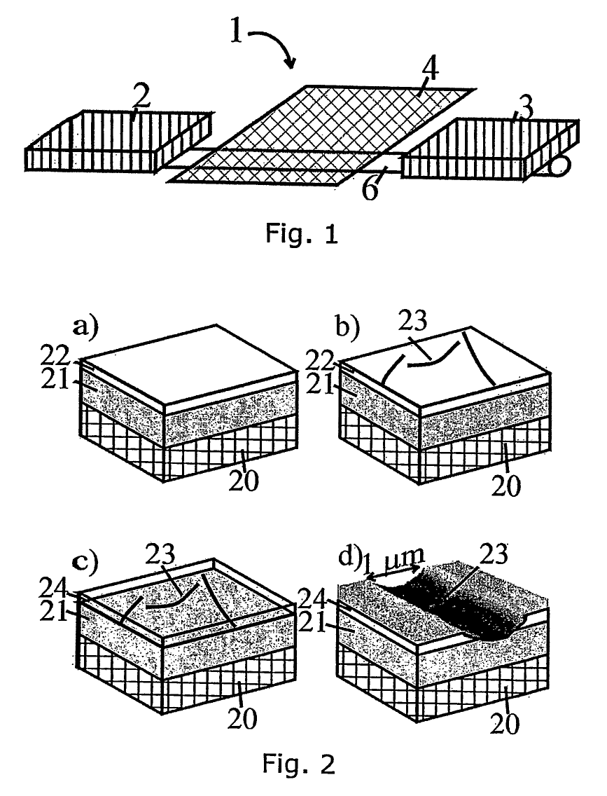

With reference to FIGS. 1, 2 and 3, the main process steps involved in the fabrication of a simple device, as well as an example of a simple device, is presented, namely the fabrication of a field effect transistor (FET).

In FIG. 1, a FET component 1 is shown. The device is a three terminal device comprising a source 2 and a drain 3 which are electrically contacted to leads (not shown), and a gate 4. The source and drain are made from the magnetic semiconductor material: Ga₁₋ₓMnₓAs (GaMnAs) but may be made from another suitable semiconductor material. The source 2 and drain 3 are connected through a single-walled nanotube 6. The source 2, drain 3, and gate 4 electrodes may be semiconductor elements formed from an epitaxial layer on top of the nanotube. A similar layout may be used to attain a single electron transistor device.

The fabrication of the device is now discussed with reference to FIGS. 2a to 2d. The fabrication of the device is conducted in one or more fabrication chambers, such as UHV MBE chambers, in which chambers the ambient conditions may be precisely controlled. The substrate 20 is a heavily n-doped GaAs with a 100 layer superlattice barrier 21 of 2 nm GaAs plus 2 nm AlAs ended by 20 nm GaAs. On top of the barrier, the wafer is capped by a first protection layer 22, as illustrated in FIG. 2a, namely a layer of amorphous As, which protects the surface of the barrier 21 and thereby ensures a clean and molecular smooth surface of the barrier which is significant for a successful overgrowth.

In FIG. 2b single walled nanotubes 23 are deposited on the surface of the amorphous As layer 22.

After the deposition of the nanotubes 23, the amorphous As layer 22 is removed by evaporation at a temperature of about T=400° C. and the GaAs surface is As enriched in an atmosphere of As at T=450-500° C. This leaves the nanotubes on the clean and molecular smooth GaAs surface.

Subsequently, as illustrated in FIG. 2c the sample is overgrown with low-temperature Ga₁₋ₓMnₓAs (T=250° C., x=5%) to obtain a thin film of epitaxial GaMnAs 24. Thin films of GaMnAs are preferred for two reasons. The minimum size of the structures that can be attained by etching of the GaMnAs film, scales with the thickness. Furthermore, the magnetic properties seems to be enhanced in thin films of GaMnAs. GaMnAs film thickness from 20 to 50 nm has been prepared. The GaMnAs is capped by 5 nm GaAs to prevent oxidation (not shown). In order to optimise the magnetic properties of the semiconductor annealing of the GaMnAs film is performed, by keeping the substrate in the MBE system at the growth temperature for a couple of hours after growth. The result is single walled nanotubes encapsulated under the GaMnAs film, as shown in FIG. 2c. UV-lithographically defined mesas are formed by etching. The semiconductor is etched by a wet etch: H₃PO₄:H₂O₂:H₂O (1:1:38), with the etching rate of 100 nm/min. The depth of the etching is controlled by the etching time.

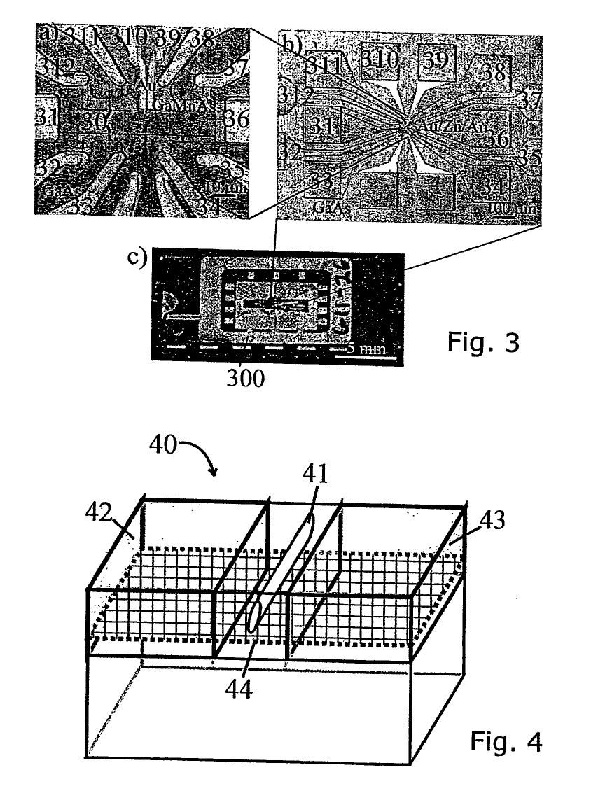

By use of e-beam lithography stripes of GaMnAs 30 were designed and etched away, leaving nanotubes as connectors between the separated GaMnAs islands, as shown in FIG. 2d, which is a zoom obtained using AFM of a junction between leads, such as between the leads 31-32, 32-33 etc. In FIG. 3a. Gold lead connected to the GaMnAs and the nanotubes are defined by e-beam lithography and lift-off. The wet etch is the same as above and the depth of the trenches are about 20 nm deeper than the GaMnAs film.

Larger pads are also fabricated using UV-lithography and lift-off technique, these contact pads serve to connect the nanotube containing devices to e.g. the legs of a chip carrier 300 as shown in FIG. 3c.

In FIG. 4a two-dimensional (2D) electron gas FET 40 is illustrated, the 2D electron gas FET is produced from a semiconductor heterostructure including an epitaxially overgrown tube 41. The source 42 and drain 43 are traditional diffused contacts. The tube 41 makes up the gate. The advantage of this device is its small dimensions, i.e. the distance between source 42 and drain 43 may be less than 5 nm. Also, the tube has a low conductance, which imply low RC value of the device. The 2D electron gas is confined in the layer designated by reference numeral 44.

Devices as illustrated in FIGS. 1 and 4 may be integrated into a network, where the tubes are utilised as successively gate electrode and active FET element.

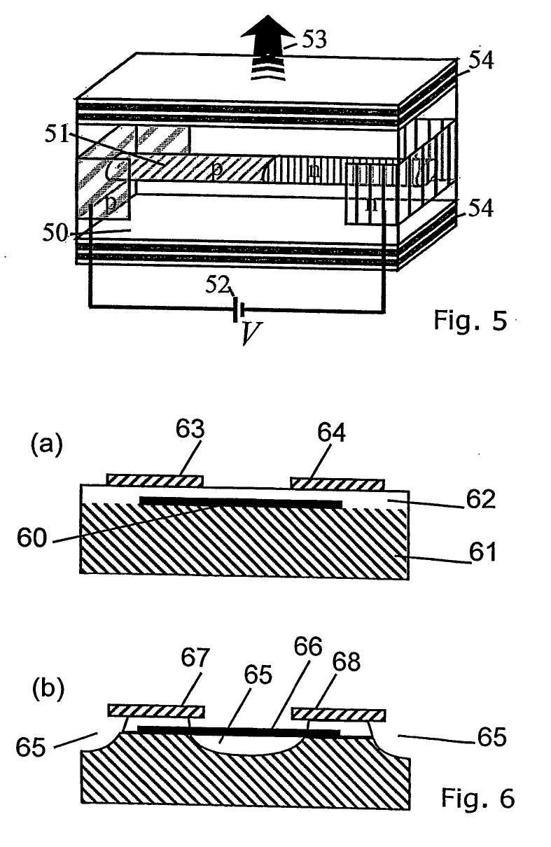

In FIG. 5, a tube laser is illustrated. A semiconductor cavity 50 is containing a semiconducting single walled nanotube 51, which is doped to form a p-n-junction. An applied voltage 52 causes electrons and holes in the tube to recombine, whereby light 53 is emitted by the tube. The semiconductor cavity is here drawn as a vertical emitting laser defined by Bragg reflectors 54.

In FIG. 6, the fabrication of a nano-electromechanical system (NEMS) is shown. In FIG. 6a, a nanosize elongated object 60, such as a carbon nanotube or a nanowire, has been placed on a substrate 61 and subsequently overgrown by an epitaxial layer 62. By use of lithographic techniques, metallic pads 63 and 64, such as Au thin film patterns, have been applied to the surface of the structure. These can function as mask elements such that trenches 65 are formed in the epitaxial layer and the substrate when being exposed to an etchant, see FIG. 6b. This process yields a free-standing elongated nanosize object 66, suspended between “pillars”. The suspended object may be electrically contacted via the independent metal contacts which may act as source 67 and drain 68 electrodes. The suspended object may be exposed to mechanical perturbations e.g. from direct manipulation or thermally induced vibrations and function as a nanoscale mechanical sensor with electrical read-out.

Although the present invention has been described in connection with preferred embodiments, it is not intended to be limited to the specific form set forth herein. Rather, the scope of the present invention is limited only by the accompanying claims.

The functionality of the present invention is not limited to those examples given in the foregoing, such that any kind of functionality within the spirit of the present invention may be envisaged.

1. A method of overgrowing elongated nanosize elements with at least one epitaxial layer, the method comprising:
(a) providing a substrate, wherein at least a top layer of the substrate has a surface configured to support epitaxial growth of an epitaxial layer;
(b) providing elongated nanosize elements onto the substrate,
(c) epitaxially overgrowing the substrate and the elongated nanosize elements with an epitaxial layer and thereby at least partly encapsulating the elongated nanosize elements with the epitaxially grown layer, and
(d) lithographically preparing one or more components in the layer.

2. A method according to claim 1, wherein the epitaxial layer comprises at least one of a semiconductor or a metal.

3. A method according to claim 1, wherein epitaxially overgrowing the substrate comprises performing a molecular beam epitaxy process.

4. A method according to claim 1, wherein epitaxially overgrowing the substrate comprises performing at least one of a chemical vapor deposition process or a liquid phase deposition process.

5. A method according to claim 1, wherein the epitaxial layer has a thickness of substantially at least one of between about 5 nm and about 5 μm, between about 5 nm and about 1 μm, between about 5 nm and about 500 nm, between about 5 nm and about 100 nm, between about 10 nm and about 75 nm, between about 20 nm and about 50 nm, or between about 20 nm and about 30 nm.

6. A method according to claim 1, wherein the epitaxial layer comprises a magnetic material.

7. A method according to claim 1, wherein the epitaxial layer comprises at least one of GaMnAs, GaAlAs, GaAs, SiGe, GaInAs, InP, Si, SiGe, GaN, GaAlN, Au, Ag, Al, Cu. a metallic alloy, MnGa, a single Heusler alloy, a double Heusler alloy. CoMnGa, Co2MnGa, a half-metallic ferromagnetics an organic semiconductors, 3,4,9,10-perylenetetracarboxylic, 3,4,9,10-dianhydride (PTCDA) or 4,9,10-perylene-tetracarboxylic-dianhydride (PTCDA) dye molecules

8. A method according to claim 1, wherein preparing the one or more components comprises performing at least one of an e-beam, X-ray beam, ion-beam, UV-lithography, AFM-lithography, nano-imprint lithography, or by shadow mask technique.

9. A method according to claim 1, wherein at least one of the substrate or the top layer of the substrate comprises a semiconductor.

10. A method according to claim 9, wherein at least one of the substrate and the top layer of the substrate is doped so as to be at least one of n-type and p-type.

11. A method according to claim 1, wherein at least the top layer of the substrate comprises a substantially mono-crystalline material.

12. A method according to claim 1, wherein at least the top layer of the substrate is grown at least in part by a molecular beam epitaxy process.

13. A method according to claim 1, wherein at least the top layer of the substrate is grown in part by at least one of a chemical vapor deposition process or a liquid phase deposition process.

14. A method according to claim 1, wherein at least one of the substrate and the top layer comprises alignment marks.

15. A method according to claim 1, wherein the substrate comprises at least one of GaAs, Si, SiN, SiC, glass, or a metal oxides.

16. A method according to claim 1, wherein at least one of the substrate or the top layer is covered with a barrier.

17. A method according to claim 16, further comprising forming a barrier between the substrate and the epitaxial layer, wherein lattice constants of at least the top layer of the substrate and the epitaxial layer are substantially matched.

18. A method according to claim 16, wherein the barrier comprises a stack of layers.

19. A method according to claim 18, wherein at least one of the layers of the stack comprises a material corresponding to at least one of the material of the substrate or the material of the top layer.

20. A method according to claim 18, wherein the barrier forms a super-lattice.

21. A method according to claim 18, wherein the stack of layers has a thickness of substantially at least one of between about 1 and about 5 nm between about 1 and about 3 nm, between about 2 and about 4 nm thick, or about 2 nm.

22. A method according to claim 18, wherein the stack of layers has a thickness of substantially at least one of between about 5 nm and about 1000 nm, between about 25 nm and about 750 nm, between about 50 nm and about 500 nm between about 75 nm and about 250 nm, or about 100 nm thick.

23. A method according to claim 1, wherein at least one of the substrate or the top layer of the substrate is covered by a first protection layer.

24. A method according to claim 16, wherein the barrier is covered by a first protection layer.

25. A method according to claim 23, wherein the first protection layer comprises a layer of at least one of amorphous arsenic, sulphur, hydrogen, or oxygen.

26. A method according to claim 1, further comprising annealing prior to epitaxially overgrowing the substrate and elongated nanosize elements.

27. A method according to claim 23, wherein the substrate comprises GaAs, the barrier comprises a super-lattice of AlAs and GaAs layers, the epitaxial layer comprises GaMnAs and the first protection layer comprises As.

28. A method according to claim 1, wherein the epitaxial layer is covered by a second protecting layer.

29. A method according to claim 28, wherein the second protecting layer has a thickness of substantially between about 2 and about 10 nm.

30. A method according to claim 1, wherein the elongated nanosize element comprises a nanowire.

31. A method according to claim 1, wherein the elongated nanosize element comprises a nanowhisker.

32. A method according to claim 30, wherein the elongated nanosize element comprises at least one of carbon, Si, SiC, B, BN, Pt, SiGe, Ge, Ag, Pb, ZnO, GaAs, GaP, InAs, InP, Ni, Co, Fe, Pb, CdS, CdSe, SnO₂, Se, Te, Si₃N₄ or MgB₂.

33. A method according to claim 1, wherein the elongated nanosize element comprises a carbon nanotube.

34. A method according to claim 33, wherein the carbon nanotubes is at least one of single-walled or multi-walled.

35. A method according to claim 33, wherein the elongated nanosized elements are at least one of insulating, semiconducting or metallic.

36. A method according to claim 33, wherein the carbon nanotubes is grown using at least one of laser ablation, an arc method, chemical vapor deposition (CVD), or high-pressure CO CVD.

37. A method according to claim 1, wherein providing the elongated nanosize element are onto the substrate comprises performing a liquid deposition process.

38. A method according to claim 1, wherein the elongated nanosize element are grown by annealing silicon carbide with or without a catalyst.

39. A method according to claim 1, wherein a catalytic material is provided to the substrate and the elongated nanosize element is grown from the catalytic material.

40. A method according to claim 1, wherein the elongated nanosize element, is manipulated in order to obtain a specific positioning of the elongated nanosize element.

41. A method according to claim 1, wherein the elongated nanosize element is configured to remove heat from the substrate.

42. A method according to claim 1, further comprising:
forming metallic contact pads; and
connecting the contact pads to the one or more components with a lithography and lift-off process.

43. A method according to claim 1, wherein the one or more components comprises an electronic component.

44. A method according to claim 1, wherein the one or more components comprises an electronic device.

45. A method according to claim 44, wherein the electronic device comprises Pan integrated circuit.

46. A method according to claim 1, further comprising repeating the providing elongated nanosize elements, the epitaxially overgrowing, and lithographically preparing, wherein a monolithic integrated circuit system is formed.

47. A method according to claim 1, wherein the elongated nanosize element containing epitaxial layer is configured to remove heat from the substrate.

48. An electronic component manufactured according to the method of claim 1.

49. An electronic device manufactured according to the method of claim 1.

50. An electronic device according to claim 49, wherein the electronic device is an integrated circuit.

51. A monolithic integrated circuit system manufactured according to the method of claim 1.

52. An optical device manufactured according to the method of claim 1.

53. A nano-electro mechanical system manufactured according to the method of claim 1.
